(19) United States
(12) Patent Application Publication
(10) Pub. No.: US 2007/0215280 A1
(43) Pub. Date: Sep. 20, 2007

(54) Semiconductor surface processing

(76) Inventors: Rajinder R. Sandhu, Castaic, CA (US); Roosevelt Johnson, Compton, CA (US); Cedric Monier, Redondo Beach, CA (US); Augusto Gutierrez-Aitken, Redondo Beach, CA (US)

Correspondence Address: PATTI, HEWITT & AREZINA LLC, ONE NORTH LASALLE STREET, 44TH FLOOR, CHICAGO, IL, 60602, US

(21) Appl. No.: 11/375,717

(22) Filed: Mar. 15, 2006

(51) Int. Cl. C03C 15/00; H01L 21/306; H01L 21/302

(52) U.S. Cl. 156/345.12; 216/89; 438/689

(57) ABSTRACT

A semiconductor surface processing method in one example comprises disposing a polishing pad in rotating engagement with a semiconductor wafer to be polished, dripping a first polishing solution onto the polishing pad at a first drip rate, and, concurrently, dripping a second polishing solution onto the polishing pad at a second drip rate.

### STATEMENT OF GOVERNMENT RIGHTS

This invention was made with Government support under Contract No. N00014-01-2-0014 awarded by the Office of Naval Research. The government has certain rights in this invention.

### BACKGROUND

This application is directed generally to semiconductor manufacturing processes and in particular to surface processing associated with semiconductor manufacture, and is more particularly directed toward a planarization method designed to remove irregularities from a semiconductor surface.

Surface crosshatch patterns associated with graded composition metamorphic buffer layer (GBL) structures have been shown to impact device performance and circuit yield. This degradation in performance and yield is particularly evident in modem semiconductor manufacturing processes involving devices such as metamorphic heterojunction bipolar transistors (HBTs), high electron mobility transistors (HEMTs), Thermovoltaic, and Optoelectronic devices.

A need arises for a chemical mechanical polishing process (CMP) that leverages oxidizing and reducing chemistries combined with surfactants to offer a surface planarization process that introduces minimal surface contamination (measured by laser light reflection techniques), thus making this approach compatible with molecular beam epitaxy (MBE) for epilayer regrowth. The delicate nature of this advanced process has been shown to remove irregularities, commonly referred to as a surface crosshatch pattern associated with the metamorphic GBL, without the introduction of subsurface damage validated by high resolution x-ray diffraction. This low damage, coupled with minimal introduction of surface contamination associated with the planarization process, allows a graded buffer layer (GBL) approach to be realized on semi-insulating substrates, suitable for the development of advanced device technologies implemented on metamorphic buffer layer templates containing surface crosshatch patterns, to achieve state of the art circuit performance and functionality.

### SUMMARY

The invention in one implementation encompasses a method. The method comprises disposing a polishing pad in rotating engagement with a semiconductor wafer to be polished, dripping a first polishing solution onto the polishing pad at a first drip rate, and, concurrently, dripping a second polishing solution onto the polishing pad at a second drip rate.

Another implementation of the invention encompasses an apparatus. The apparatus comprises means for disposing a polishing pad in rotating engagement with a semiconductor wafer to be polished, means for dripping a first polishing solution onto the polishing pad at a first drip rate, and means for concurrently dripping a second polishing solution onto the polishing pad at a second drip rate.

### DESCRIPTION OF THE DRAWINGS

Features of illustrative implementations of the invention will become apparent from the description, the claims, and the accompanying drawings in which:

FIG. 1 illustrates a silicon ingot.

FIG. 2 shows a silicon wafer with an epitaxial layer on its upper surface.

FIG. 3 depicts a semiconductor substrate with a graded buffer layer structure.

FIG. 4 illustrates an apparatus suitable for carrying out a polishing method in accordance with the present invention.

### DETAILED DESCRIPTION

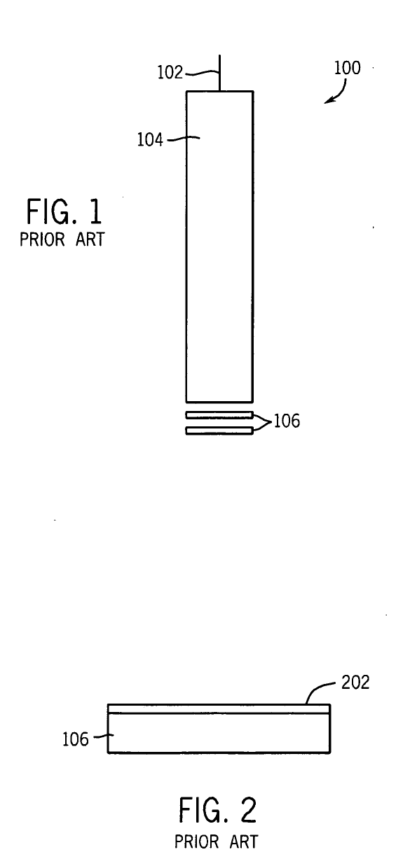

In known semiconductor manufacturing processes, wafer-scale manufacturing is generally used, in which multiple copies of a desired circuit or device are fabricated on a relatively large silicon wafer, with individual circuits or devices trimmed from the wafer upon process completion. FIG. 1 illustrates a silicon ingot 104, which is typically formed by immersing a seed crystal in molten silicon. The ingot 104 is slowly withdrawn from the molten silicon, using suspension rod 102, as crystal growth proceeds. Since crystal growth tends to be uniform in all directions, the ingot 104 is substantially cylindrical. After the ingot 104 is completely withdrawn from the molten silicon, it is generally ground to a uniform circular cross-section, and individual silicon wafers 106 are sliced from the ingot 104.

Even in conventional semiconductor fabrication, in which large geometry CMOS (complementary metal oxide semiconductor) devices, for example, may be formed, it is important that the silicon on which the devices are fabricated be relatively free of impurities and defects in the crystal structure. To ensure this condition, a layer of silicon 202 is grown on the surface of the wafer 106 via an epitaxial growth process, as shown in FIG. 2.

In epitaxial growth, exposed silicon on the wafer surface is used as a seed for additional silicon crystal growth. Typically, the wafer 106 is exposed to silane (and perhaps dopant gases) at high temperatures. Dopant gases are used to form doped epitaxial regions, such as lightly or heavily doped n-type or p-type epitaxial regions, that may be required depending upon the types of devices or circuits being fabricated. Buried layers may also be created, using diffusion or ion-implantation processes, for example, prior to epitaxial growth. An epitaxially grown layer is often referred to as “epi.”

In modern processes designed for fabrication of higher performance devices, a combination of In_{0.52}Al_{0.48}As/In_{0.53}Ga_{0.48}As/In_{0.52}Al_{0.48}As epilayers grown on semi-insulating InP substrates may be utilized due to the attractive electron transport properties of the InₓGa₁₋ₓAs base layer. It is well known that increasing the indium composition in the InₓGa₁₋ₓAs layer leads to a reduction in electron effective mass and an associated increase in electron mobility. In addition to improving the transistor transport properties, the higher indium composition in the InₓGa₁₋ₓAs layer leads to a reduction in transistor turn-on voltage. Therefore, increasing the indium composition in the InₓGa₁₋ₓAs layer of the transistors allows for state of the art device performance at ultra low powers over conventional transistors with lattice matched In_{0.53}Ga_{0.47}As layers.

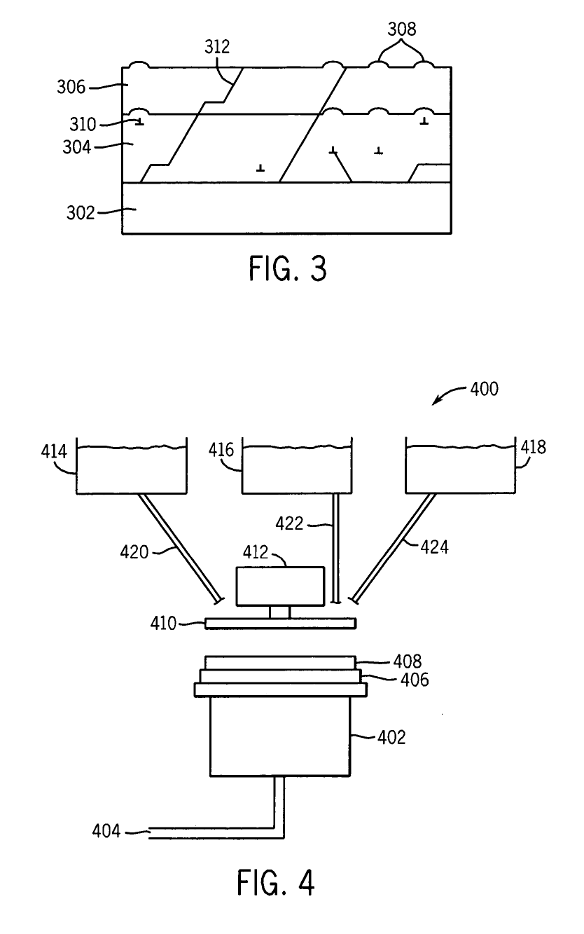

However, since the higher indium content (X_{In}>0.53) devices are no longer lattice-matched to InP (5.868 Å), a metamorphic growth approach is indicated to allow for lattice grading to offer a semi-insulating template on InP with lattice parameter toward that of InAs (5.868Å). The metamorphic graded composition buffer layer (GBL) is implemented to accomplish the lattice parameter grade. FIG. 3 depicts a wafer structure based upon an InP substrate 302.

Molecular beam epitaxial (MBE) growth is used to deposit the GBL through direct deposition of atomic (or polyatomic molecular) species at a substrate surface. The species being deposited are generally contained within effusion cells having controllable apertures and cell temperatures. The growth rate for an epitaxial layer deposited in this fashion is generally determined by effusion cell temperature and substrate temperature, while the ratio of atom types deposited to form a specific epitaxial layer is controlled through manipulating each effusion cell's shutter aperture. This MBE process should not be confused with MOCVD (Molecular Organometallic Chemical Vapor Deposition). With MOCVD, the required atoms are introduced to the substrate via volatile molecular organometallic species (carriers).

Material defects present in the GBL due to the lattice grading introduce surface undulations during subsequent epilayer growth. Principally, the surface undulations are caused by dislocations within the GBL 304 that are known as misfit 310 and threading 312. These dislocation types often cause an unacceptable crosshatch pattern on the outer surface of MBE-produced layers that can propagate through outer device layers 306 and cause surface undulations 308. The process described herein is directed toward an MBE-compatible chemical mechanical polishing process (CMP) for thin (less than a micron thick) mixed Cation-Anion Group III-V based semiconductor epilayers with high indium content toward that of InAs. Of course, the process is also suitable for other layer thicknesses and compositions as well. The process introduces no measurable subsurface damage by x-ray diffraction, which enables the realization of a graded buffer layer approach suitable for the development of advanced device technologies to achieve state of the art circuit performance and functionality.

A suitable apparatus is illustrated in FIG. 4, generally depicted by the numeral 400. A wafer 408 to be polished is secured to a carrier 406 that is in mechanical contact with a vacuum fixture 402. By applying vacuum to the vacuum fixture 402 through vacuum line 404, the wafer 408 is secured in position for the polishing process. The apparatus 400 further includes a polishing pad 410 coupled to a drive motor 412. The polishing pad 410 can be brought into engagement with the wafer 408, and the engagement force can be measured and controlled. A first polishing solution reservoir or tank 414 is positioned proximate the polishing pad 410, and includes an outlet tube 420 with a valve that can accurately set the drip rate in drops per minute. Of course, the flow of polishing solution may also be shut off completely. A second polishing solution container 418 is also positioned proximate the pad 410, with a similar outlet tube 424 and control valve. A reservoir or tank 416 for DI water is also provided, with an outlet tube 422 through which the drip rate of DI onto the pad 410 may be controlled through an appropriate range of drip rates measured in drops per second.

A polishing pad 410 is then applied to the polishing apparatus 400. In one implementation, the polishing pad 410 is a Logitech black felt polishing pad. Next, Sodium Hypochlorite (NaOCl) solution may be mixed with DI water at a range of ratios, from about 1:1 to about 5:1, to form a solution having a pH greater than 8. A surfactant is added to the Sodium Hypochlorite solution, and the temperature of the solution is allowed to stabilize at approximately room temperature. The surfactant may be a polyol polysiloxane hydroxyl complex in ethylene glycol. More specifically, the surfactant may contain ethylene glycol, hydrated silica, and aliphatic hydrocarbons. After temperature stabilization, the mixture is placed into the proper polishing solution container 414. The rinse container 416 is filled with DI water.

A second chemical solution composed of Citric acid (C₆H₈O₇), to offer an oxidizing agent in the polishing chemistry, is then mixed with deionized water (DI H₂O) in a range of ratios from about 1:1 to about 5:1 to yield a solution having a pH less than 7. The temperature of this solution is allowed to stabilize at about room temperature, and the citric acid mixture is also placed into the proper polishing solution container 418.

To begin the actual polishing process with a production wafer 408, the InP substrate with cross-hatch surface pattern is placed on the polishing apparatus. Then, the wafer 408 to be polished is inspected for defects and the results recorded. Next, the drip rates for each etch solution are set. The sodium hypochlorite should be set to drip at about 1 to 10 drops per second, and the citric acid mixture should be set to drip at about 1 to 10 drops per second. The jig with the wafer to be polished is then positioned on the polishing plate, and the rotation speed of the pad is set between about 5 and about 80 rpm, carefully checking to make sure that the pad on the jig is rotating properly. The contact force between the polishing pad 410 and the wafer 408 to be polished is set between about 0.5 kilogram and about 2 kilograms. The polishing time is set between about 0.5 hour and about 6 hours. After completion of the polishing process and any desired post-polishing procedures, the polished wafer is inspected under a microscope to characterize the wafer surface crosshatch pattern and determine whether additional polishing is required to planarize the surface.

The steps or operations described herein are just examples. There may be many variations to these steps or operations without parting from the spirit of the invention. For instance, the steps may be performed in a differing order, or steps may be added, deleted, or modified.

Although illustrative implementations of the invention have been depicted and described in detail herein, it will be apparent to those skilled in the relevant art that various modifications, additions, substitutions, and the like can be made without departing from the spirit of the invention and these are therefore considered to be within the scope of the invention as defined in the following claims.

1. A method, comprising the steps of:
disposing a polishing pad in rotating engagement with a semiconductor wafer to be polished;
dripping a first polishing solution onto the polishing pad at a first drip rate, and, concurrently
dripping a second polishing solution onto the polishing pad at a second drip rate.

2. The method in accordance with claim 1, wherein the step of disposing a polishing pad in rotating engagement with a semiconductor wafer to be polished further comprises the steps of:
securing the wafer to be polished to a mounting base;
engaging the polishing pad with the wafer to be polished at a contact force of between about 0.5 kilogram and about 2 kilograms; and
rotating the pad at an angular velocity of between about 5 and 80 rpm.

3. The method in accordance with claim 1, wherein the step of dripping a first polishing solution onto the polishing pad at a first drip rate further comprises the steps of:
preparing the first polishing solution by mixing sodium hypochlorite with DI water and surfactant,
placing the first polishing solution into a first polishing solution container;
setting the drip rate for the first polishing solution at a rate between about 1 drop per second and about 10 drops per second.

4. The method in accordance with claim 3, wherein the step of preparing the first polishing solution further comprises the steps of:
mixing sodium hypochlortie with DI water at a ratio of between about 1:1 and about 5:1; and
adding approximately 1 to 20 drops of a surfactant for every 1000 ml of sodium hypochlorite;
such that resultant pH of the first polishing solution is greater than approximately 8.

5. The method in accordance with claim 1, wherein the step of dripping a second polishing solution onto the polishing pad at a second drip rate further comprises the steps of:
preparing the second polishing solution by mixing citric acid with DI water;
placing the second polishing solution into a second polishing solution container;
setting the drip rate for the second polishing solution at a rate between about 1 drop per second and about 10 drops per second.

6. The method in accordance with claim 5, wherein the step of preparing the second polishing solution further comprises the step of mixing citric acid with DI water at a ration of between about 1:1 and about 5:1, such that resultant pH of the second polishing solution is less than about 7.

7. A method comprising the steps of:
disposing a polishing pad in rotating engagement with a semiconductor wafer to be polished;
securing the wafer to be polished to a mounting base;
preparing a first polishing solution by mixing sodium hypochlorite with DI water and a surfactant;
placing the first polishing solution into a first polishing solution container;
setting the drip rate for the first polishing solution at a rate between about 1 drop per second and 10 drops per second;
preparing a second polishing solution by mixing citric acid with DI water;
placing the second polishing solution into a second polishing solution container; and
setting the drip rate for the second polishing solution at a rate between about 1 drop per second and 10 drops per second, such that the first and second polishing solutions drip onto the polishing pad concurrently.

8. The method in accordance with claim 7, further comprises the steps of:
engaging the polishing pad with the wafer to be polished at a contact force of between about 0.5 kilogram and about 2 lilograms; and
rotating the pad at an angular velocity of between about 5 and 80 rpm.

9. An apparatus comprising:
means for disposing a polishing pad in rotating engagement with a semiconductor wafer to be polished;
means for dripping a first polishing solution onto the polishing pad at a first drip rate, wherein the first polishing solution is prepared by mixing sodium hypochlorite with DI water and a surfactant which contains ethylene glycol, hydrated silica, and aliphatic hydrocarbons; and
means for concurrently dripping a second polishing solution onto the polishing pad at a second drip rate.

10. The apparatus of claim 9, wherein the means for disposing a polishing pad in rotating engagement with a semiconductor wafer to be polished further comprises:
means for securing the wafer to be polished to a mounting base;
means for engaging the polishing pad with the wafer to be polished at a contact force of between about 0.5 lilogram and about 2 lilograms; and
means for rotating the pad at an angular velocity of between about 5 and 80 rpm.

11. The apparatus of claim 9, wherein the means for dripping a first polishing solution onto the polishing pad at a first drip rate further comprises:
means for preparing the first polishing solution;
means for dispensing the first polishing solution from a first polishing solution container;
means for setting the drip rate for the first polishing solution at a rate between about 1 drop per second and 10 drops per second.

12. The apparatus of claim 11, wherein the means for preparing the first polishing solution further comprises;
means for mixing sodium hypochlorite with DI water at a ratio of between about 1:1 and about 5:1; and
means for adding approximately 1 to 20 drops of a surfactant for every 1000 ml of sodium hypochlorite;
such that resultant pH of the first polishing solution is greater than approximately 8.

13. The apparatus of claim 9, wherein the means for dripping a second polishing solution onto the polishing pad at a second drip rate further comprises:
means for preparing the second polishing solution by mixing citric acid with DIH water;
means for dispensing the second polishing solution from a second polishing solution container;
means for setting the drip rate for the second polishing solution at a rate between about 1 drop per second and 10 drops per second.

14. The apparatus of claim 13, wherein the means for preparing the second polishing solution further comprises means for mixing citric acid with dI water at a ratio of between about 1:1 and about 5:1, such that resultant pH of the second polishing solution is less than about 7.

15. An apparatus comprising:
means for disposing a polishing pad in rotating engagement with a semiconductor wafer to be polished;
means for securing the wafer to be polished to a mounting base;
means for preparing a first polishing solution by mixing sodium hypochlorite with dI water and a surfactant which contains ethylene glycol, hydrated silica, and allphatic hydrocarbons;
means for dispensing the first polishing solution from a first polishing solution container;
means for setting the drip rate for the first polishing solution at a rate between about 1 drop per second and 10 drops per second;
means for preparing a second polishing solution by mixing citric acid with dI water;
means for dispensing the second polishing solution from a second polishing solution container; and
means for setting the drip rate for the second polishing solution at a rate between about 1 drop per second and 10 drops per second, such that the first and second polishing solutions drip onto the polishing pad concurrently.

16. The apparatus of claim 15, further comprising:
means for engaging the polishing pad with the wafer to be polished at a contact force of between about 0.5 lilogram and about 2 kilograms; and
means for rotating the pad at an angular velocity of between about 5 and 80 rpm.

17. The apparatus of claim 15, wherein the means for preparing the first polishing solution further comprises:
means for mixing sodium hypochlorite with dI water at a ratio of between about 1:1 and about 5:1; and
means for adding approximately 1 to 20 drops of a durfactant for every 1000 ml of sodium hypochlorite;
such that resultant pH of the first polishing solution is greater than approximately 8.

18. The apparatus of claim 15, wherein the means for preparing the second polishing solution further comprises means for mixing citric acid with dI water at a ratio of between about 1:1 and about 5:1, such that resultant pH of the second polishing solution is less than about 7.
